(19) United States
(12) Patent Application Publication
(10) Pub. No.: US 2011/0316526 A1
(43) Pub. Date: Dec. 29, 2011

(54) ARRANGEMENT AND METHOD FOR MEASURING A MAGNETIC MATERIAL IN A REGION OF ACTION

(75) Inventors: Giovanni Nisato, Riehen (CH); Hans Marc Bert Boeve, Hechtel-Eksel (BE)

(73) Assignee: KONINKLIJKE PHILIPS ELECTRONICS N.V., EINDHOVEN (NL)

(21) Appl. No.: 13/203,505

(22) PCT Filed: Mar. 1, 2010
(86) PCT No.: PCT/IB10/50876

§ 371 Date: Sep. 13, 2011

(30) Foreign Application Priority Data
Mar. 9, 2009 (EP) 09154584.8

(51) Int. Cl. G01R 35/00

(52) U.S. Cl. 324/202

(57) ABSTRACT

The present invention relates to an arrangement (10) for measuring small amounts of a first medium (202) in a third medium (206) and/or of a substance in the first medium (202), said third medium (206) comprising said first medium (202) and a second medium (204), said second medium (204) comprising a known concentration of a magnetic material, wherein said arrangement comprises: magnetization means (12) for providing a variable magnetic field (20) in a region of action (22), in which a probe (18; 208) of said third medium (206) is placed for measurement, receiving means (14) for acquiring a detection signal of the magnetization of said probe (12) in said region of action (22) after application of said variable magnetic field (20), and evaluation means (214) for evaluating said detection signal and comparing it to calibration measurements of the magnetization of at least one calibration sample to derive an information about the amount of said first medium (202) in said third medium (206) and/or of said substance in said first medium (202).

### FIELD OF THE INVENTION

The present invention relates to an arrangement for measuring small amounts of a first medium in a third medium and/or of a substance in the first medium. Further, the present invention relates to a method for measuring small amounts of a first medium in a third medium and/or of a substance in the first medium.

### BACKGROUND OF THE INVENTION

An arrangement of this kind is known from Biederer, S. and Gleich, B. (2008), “A Spectrometer for Magnetic Particle Imaging” in IFMBE Proceedings, Volume 22, pp. 2313-2316. In the arrangement described in that publication, a magnetic particle imaging scanner without spatial encoding is used. The spectrometer comprises a transmit coil for applying a time varying magnetic field to nanoparticles of a probe to be measured and a receive coil for detecting the magnetization of the particles in the probe chamber. The spectrometer detects the concentration of magnetic particles in the probe chamber since the magnetization level scales lineary with the concentration. However, this method just measures the concentration of the magnetic particles.

Further, radioactively labeled molecules are routinely used to measure small amounts and concentrations in fluids or solid materials, as required in medical, biological assay, drug device developments. The advantage of radioactively labeled molecules is the high sensitivity and, depending on the specific isotope, the low background signal level which allows for quantitative measurements. The disadvantages are again isotope dependent, and have to do with toxicity of the materials. In practice, special experimental precautions have to be taken, and often administrative permission has to be requested to monitor the experimental practice. This restricts the application of such techniques to both specific locations and trained personnel. Thus, these methods require appropriate infrastructure for safety and produce hazardous waste.

Magnetic particle imaging (MPI) is generally known, e.g. from German patent application DE 101 51 778 A1. MPI is a method for imaging distributions of magnetic nano-particles which combines high sensitivity with the ability of fast dynamic imaging, making it a promising candidate for medical imaging applications. The MPI system measures the magnetization response of a point-like sample at a large number of spatial positions corresponding to the number of image pixels or voxels. However, this system and method is time-consuming, complicated and expensive.

### SUMMARY OF THE INVENTION

It is an object of the present invention to provide an improved arrangement and method for a fast, accurate and safe measurement of small amounts of one medium in another medium and/or of a substance in a medium, without using radioactively labeled molecules.

According to a first aspect of the present invention an arrangement is presented for measuring small amounts of a first medium in a third medium and/or of a substance in the first medium, said third medium comprising said first medium and a second medium, said second medium comprising a known concentration of a magnetic material wherein said arrangement comprises:
magnetization means for providing a variable magnetic field in a region of action, in which a probe of said third medium is placed for measurement,
receiving means for acquiring a detection signal of the magnetization of said probe in said region of action after application of said variable magnetic field, and
evaluation means for evaluating said detection signal and comparing it to calibration measurements of the magnetization of at least one calibration sample to derive an information about the amount of said first medium in said third medium and/or of said substance in said first medium.

According to a second aspect of the present invention a method is presented for measuring small amounts of a first medium in a third medium and/or of a substance in the first medium, said third medium comprising said first medium and a second medium, said second medium comprising a known concentration of a magnetic material, which method comprises the steps of:
generating a variable magnetic field in the region of action, in which a probe of said third medium is placed for measurement,
acquiring a detection signal of the magnetization of said probe in said region of action after application of said magnetic field, and
comparing said detection signal to calibration measurements of the magnetization of at least one calibration sample to derive an information about the amount of said first medium in said third medium and/or of said substance in said first medium.

By comparing the detection signal to calibration measurements of at least one calibration sample, it is possible to measure small amounts of a medium or a substance in another medium, wherein the first medium or the substance does not comprise labeled molecules or tracer material, respectively. The amount of one medium in another medium and/or the amount of a substance in one medium can be measured thereby in-vitro or in a patient's body very accurate. Overall, this arrangement and method allow a fast, accurate and safe operation, a reliable quantification of the concentration of a medium or a substance which is intrinsically radiation free and non-toxic. Further, by the present invention a low level of magnetic tracers are present in biological samples and the environment leading to a low in-sample noise. Still further the hazardous waste is reduced, the method is easy to use since there is no need to add a light-emitting scintillation cocktail, and it is suitable for direct measurement in fluid and solid phases.

The invention does refer to a new aspect related to the use of a tracer material which can be used in MPS (Magnetic Particle Spectroscopy) and MPI. In this technique, non-linear magnetic spectroscopy is performed on the local magnetic response of in-vivo tracers upon the application of multi-dimensional ac magnetic fields. For a magnetic particle to react to an ac magnetic field, different mechanisms may be responsible: (1) Néel rotation in the case of single-domain particles, (2) geometric Brownian rotation, and (3) domain wall movement for multi-domain particles. For MPI, magnetic particles are optimized for the Néel rotation, which allows for a fast response to the external field so that the non linear magnetization response can be analyzed in a good number of harmonics. These mechanisms lead to the reliable quantification of the average number of tracer particles in a measured voxel, or particle concentration.

A number of tracer materials are available that give a good signal in MPS/MPI, referred to as SuperParamagnetic Iron Oxide (SPIO) material such as Resovist®. These materials are commercially available and approved for parental administration in humans such as an MRI imaging contrast agent. Such material comprises colloidally stabilised monodomain magnetic nanoparticles.

According to an embodiment of the present invention, it is preferred that the magnetization means are adapted for generating a magnetic selection field having a pattern in space of its magnetic field strength such that a first sub-zone having a low magnetic field strength and a second sub-zone having a higher magnetic field strength are formed in a region of action, wherein drive means are adapted for changing the position in space of the two sub-zones in the region of action by means of a magnetic drive field so that their magnetization of the magnetic material changes locally. By generating a magnetic selection field, a system is possible to measure a spatial distribution of magnetic particles or magnetic tracer material and to provide a mapping, respectively. This embodiment combines a magnetic particle spectrometer (MPS) and a magnetic particle imaging (MPI) scanner.

According to an embodiment of the present invention, it is further preferred that said calibration sample comprises a known volume of said second medium. The advantage of a calibration sample having a known volume is that an acquired detection signal of the magnetization of the probe to be measured can be correlated to the amount of magnetic material in said second medium. This provides a high accuracy of the measurement.

It is furthermore preferred according to the present invention that said at least one calibration sample comprises a plurality of calibration samples having different concentrations of the magnetic material. The advantage of the plurality of calibration samples is that calibration factors which are derived from a plurality of calibration samples are more accurate, since the calibration factors scale with the effective concentration of magnetic material.

According to an embodiment of the present invention, it is preferred that said at least one calibration sample comprises a plurality of calibration samples having different volumes of said second medium. The advantage of different calibration samples having different volumes is that the calibration factor which is derived from these measurements is more accurate. Further, the measurement of the calibration factor is easier, since the different probes could be prepared by adding a defined volume to one calibration sample to provide different volumes of the second medium. Further, the calibration samples could be provided by injecting a defined volume into biological tissues to provide different calibration samples, e.g. by injecting a medium transdermal into a patient's body.

It is furthermore preferred according to the present invention that the magnetic field is a homogeneous alternating magnetic field. The advantage of such a magnetic field is that the magnetic field has only one spatial component in the region of action and therefore the effort to evaluate the signal of the magnetization of the magnetic material is reduced. The calculation formula to calculate the concentration from the detection signal can thus be simplified, whereby the time consumption and the required amount of computer memory can be reduced.

In a further preferred embodiment of the present invention the receiving means are adapted for deriving said detection signal from the amplitude of one harmonic of the magnetic dipole moment. This is an advantage, since the receiving means and the evaluation means to evaluate the detection signal can be simplified and the evaluation of the signal is less time-consuming.

It is further preferred according to the present invention, that the magnetic field comprises one magnetic field strength. The advantage of one magnetic field strength is that the magnetization means can be simplified and the evaluation of the detection signal is less time-consuming and the receiving means for acquiring the detection signal can be simplified.

In another embodiment of the present invention the magnetic field comprises different magnetic field strengths. The advantage of using different magnetic field strengths is that the measurement of the probe is more accurate.

It is preferred according to the present invention that the magnetic material comprises magnetic nanoparticles, in particular colloidally stabilised monodomain magnetic nanoparticles. Further, magnetic labeled molecules could be selected for special application and could be used for measurements of and/or in combination with chemical reactions in biological tissues or in a patient's body.

According to a further embodiment the first medium is a medical or biological assay and the substance in the first medium is an active drug substance.

It is preferred according to the present invention that the at least one calibration sample is provided by injection of said second medium into the third medium. The advantage of injecting said second medium into the third medium is that the calibration samples could be prepared with a reduced effort by injecting sequentially defined portions of the second medium in one sample and could be prepared as a transdermal sample in a patient's body.

### BRIEF DESCRIPTION OF THE DRAWINGS

These and other aspects of the invention will be apparent from and elucidated with reference to the embodiment(s) described hereinafter. The following drawings

FIG. 1 shows a schematic view of a magnetic particle spectrometer arrangement in accordance with the present invention,

FIG. 2 shows an enlarged view of a magnetic particle present in the region of action,

FIGS. 3a, b and c show the magnetization characteristics of such particles,

FIG. 4 shows a schematic diagram illustrating the method according to the present invention, and

FIG. 5 shows a magnetic dipole measurement of calibration samples having different volumes.

### DETAILED DESCRIPTION OF THE INVENTION

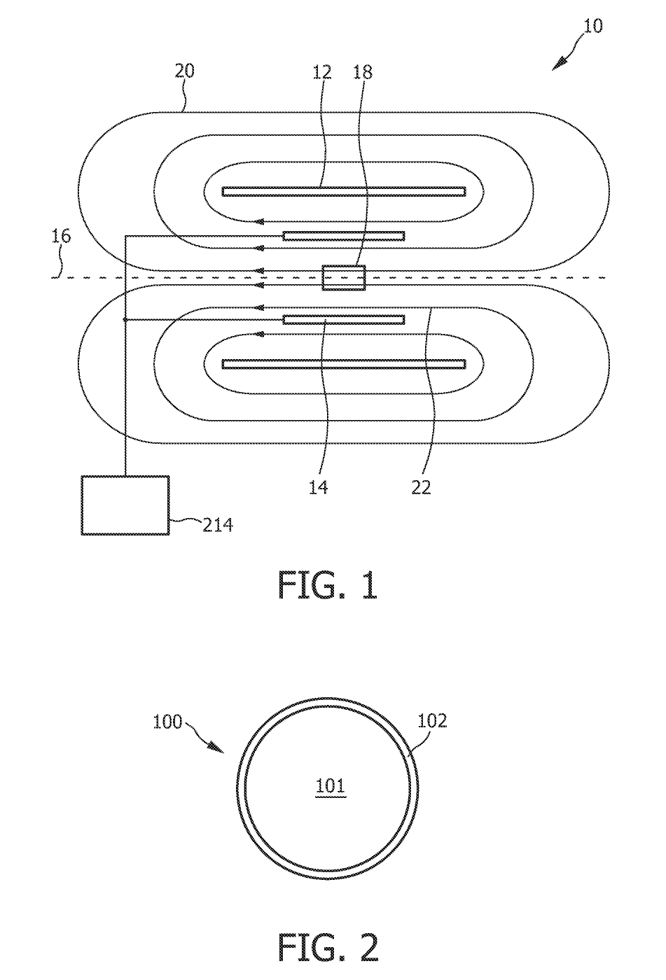

FIG. 1 shows an object to be examined by means of a magnetic particle spectroscope (MPS) arrangement 10 according to the present invention. The MPS arrangement 10 comprises a transmission coil 12 and a receiving coil 14, which are arranged coaxial to each other. The receiving coil 14 is arranged coaxial within the transmission coil 12. The transmission coil and the receiving coil are axially symmetric to a common axis 16. A probe 18 is disposed on the axis 16 within the receiving coil 14. The transmission coil 12 generates a magnetic field 20, which is homogeneous within the transmission coil 12 and which is axial symmetric to the axis 16. The probe 18 is disposed in a probe chamber 22 which is located in the center of the receiving coil.

The transmission coil 12 is adapted to provide a homogeneous variable magnetic field within the probe chamber 22. The receiving coil 14 is adapted to receive a magnetization response from particles 100 (not shown in FIG. 1), which are arranged in the probe chamber 22 and the probe 18 respectively. In FIG. 1 the probe is an arbitrary object, however this probe 18 can be either an in-vitro sample or a human or animal patient who is arranged within the probe chamber 22. The probe 18 comprises magnetic particles 100 which are disposed in the probe chamber 22, e.g. by means of liquid (not shown) comprising the magnetic particles 100 or tracer material injected into the sample or the body of the patient.

In another embodiment, the arrangement 10 is provided with at least one additional transmission coil and/or at least one additional permanent magnet to provide a magnetic selection field and to change the magnetization of the particles 100 locally.

FIG. 2 shows an example of a magnetic particle 100 of the kind used together with an arrangement 10 of the present invention. It comprises for example a spherical substrate 101, for example, of glass which is provided with a soft-magnetic layer 102 which has a thickness of, for example, 5 nm and consists, for example, of an iron-nickel alloy (for example, Permalloy). This layer may be covered, for example, by means of a coating layer 103 which protects the particle 100 against chemically and/or physically aggressive environments, e.g. acids. The magnetic field strength of the magnetic field 20 required for the saturation of the magnetization of such particles 100 is dependent on various parameters, e.g. the diameter of the particles 100, the used magnetic material for the magnetic layer 102 and other parameters.

In the case of e.g. a diameter of 10 μm, a magnetic field of approximately 800 A/m (corresponding approximately to a flux density of 1 mT) is then required, whereas in the case of a diameter of 100 μm a magnetic field of 80 A/m suffices. Even smaller values are obtained when a coating 102 of a material having a lower saturation magnetization is chosen or when the thickness of the layer 102 is reduced.

For further details of the preferred magnetic particles 100, the corresponding parts of DE 10151778 are hereby incorporated by reference, especially paragraphs 16 to 20 and paragraphs 57 to 61 of EP 1304542 A2 claiming the priority of DE 10151778.

Another suitable material is, for instance, described in EP 1738773 and EP 1738774 where magnetic nanoparticles optimised for MPI have been described, i.e. Fe oxide based SPIO (i.e. superparamagnetic nanoparticles) comprising magnetic nanoparticles, in particular colloidally stabilised monodomain magnetic nanoparticles.

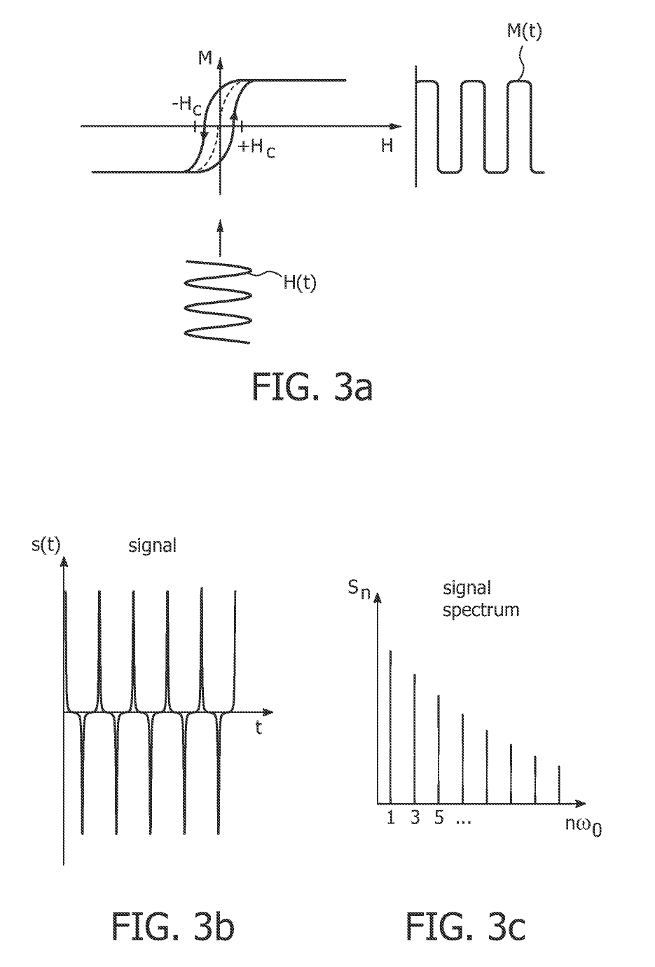

FIG. 3a shows the magnetization characteristic, that is, the variation of the magnetization M of a particle 100 (not shown in FIG. 3a) as a function of the field strength H at the location of that particle 100, in a dispersion with such particles. It appears that the magnetization M no longer changes beyond a field strength+H_{c} and below a field strength−H_{c}, which means that a saturated magnetization is reached. The magnetization M is not saturated between the values +H_{c} and −H_{c}.

FIG. 3a illustrates the effect of a sinusoidal magnetic field H(t) at the location of the particle 100 where the absolute values of the resulting sinusoidal magnetic field H(t) (i.e. “seen by the particle 100”) are lower than the magnetic field strength required to magnetically saturate the particle 100, i.e. in the case where no further magnetic field is active. The magnetization of the particle 100 or particles 100 for this condition reciprocates between its saturation values at the rhythm of the frequency of the magnetic field H(t). The resultant variation in time of the magnetization is denoted by the reference M(t) on the right hand side of FIG. 3a. It appears that the magnetization also changes periodically and that the magnetization of such a particle is periodically reversed.

The dashed part of the line at the centre of the curve denotes the approximate mean variation of the magnetization M(t) as a function of the field strength of the sinusoidal magnetic field H(t). As a deviation from this centre line, the magnetization extends lightly to the right when the magnetic field H increases from −H_{c} to H_{c} and slightly to the left when the magnetic field H decreases from +H_{c} to −H_{c}. This known effect is called a hysteresis effect which underlies a mechanism for the generation of heat. The hysteresis surface area which is formed between the paths of the curve and whose shape and size are dependent on the material, is a measure for the generation of heat upon variation of the magnetization.

Next, signal generation shall be described. The basic principle of signal generation in MPS (and MPI) relies on the non-linear magnetization response M(H) of ferromagnetic particles to an applied magnetic field H. An oscillating drive field H_{D}(t) of sufficient amplitude leads to a magnetization response M(t) of the particles, which has a different spectrum of higher harmonics than the drive field. If, for instance, a harmonic drive field is used, the drive field spectrum only contains the base frequency, whereas the particle response also contains multiples of the base frequency. The information contained in these higher harmonics is used for MPS. Experimentally, the time-dependent change in particle magnetization is measured via the induced voltage in the receive coil 14. Assuming the receive coil 14 with sensitivity Sᵣ(r), the changing magnetization induces a voltage

$$V ( t ) = - {μ}_{0} \frac{d}{d t} {\int }_{object} {S}_{r} ( r ) \cdot M ( r , t ) {d}^{3} r \qquad ( 1 )$$

according to Faraday's law. μ₀ is the magnetic permeability of vacuum. The receive coil sensitivity Sᵣ(r)=Hᵣ(r)/I₀ derives from the field Hᵣ(r) the coil would produce if driven with a unit current I₀. In the following, the sensitivity of the receive coil is approximated to be homogeneous over the region of interest, i.e., Sᵣ(r) is constant. If Mₓ(r,t) is the magnetization component picked up by a receive coil in x direction, the detected signal can be written as

$$V ( t ) ∝ - \frac{d}{d t} {\int }_{object} {M}_{x} ( r , t ) {d}^{3} r . \qquad ( 2 )$$

Now, consider the signal s(r,t) generated by a point-like distribution of particles. The volume integration can be removed and the particle magnetization Mₓ(r,t) is determined by the local field H(r,t). For the moment, the field is assumed to have only one spatial component Hₓ(r,t) (shown in FIG. 1), which is pointing in receive-coil direction. The signal (shown in FIG. 3b) can then be written as

$$\begin{matrix}s ( r , t ) = - \frac{d}{d t} M ( r , t ) \\ = - \frac{d}{d t} M ( H ( r , t ) ) \\ = - \frac{\partial M}{\partial H} \frac{d H ( r , t )}{d t} \\ = - {M}^{′} ( H ) \frac{d H ( r , t )}{d t} .\end{matrix} \qquad ( 3 )$$

Since this equation holds for all orientations where the field is aligned with the direction of the acquired magnetization component, the subscript x has been omitted. Equation 3 shows that high signal results from the combination of a steep magnetization curve with rapid field variations. Fourier expansion of the periodic signal s(t) generated by applying a homogeneous drive field H(r,t)=H_{D}(t) yields the signal spectrum Sₙ, as shown in FIG. 3c. Intensity and weight of higher harmonics in the spectrum are related to the shape of the magnetization curve M(H), and to the waveform and amplitude of the drive field H_{D}(t). To illustrate their influence on the spectrum, a number of representative cases are shown in FIG. 7.

The step function relates to an immediate particle response and creates a spectrum that is rich in high harmonics. The spectral components have constant magnitude at odd multiples of the drive frequency. Even harmonics are missing due to the sine-type pattern of the time signal s(t). The step function corresponds to an ideal particle response and represents the limiting case for the achievable weight of higher harmonics. For this magnetization curve, triangle and sine drive fields yield the same result.

FIG. 3a shows a particle magnetization as given by the Langevin function

M(ξ)=M₀(eothξ−1/ξ), (4)

where ξ is the ratio between magnetic energy of a particle with magnetic moment m in an external field H, and thermal energy:

$$ξ = \frac{m H}{kT} . \qquad ( 5 )$$

A higher magnetic moment results in a steeper magnetization curve and creates more higher harmonics for a given drive field amplitude. Alternatively, high harmonics can be generated from a shallow curve using faster field variations, e.g., induced by a higher drive field amplitude. It should be noted that MPI uses ferromagnetic particles to obtain a sufficiently steep magnetization curve. For low concentrations, however, their mutual interactions can be neglected and they can be treated like a gas of paramagnetic particles with extremely large magnetic moment, a phenomenon also known as “super-paramagnetism”.

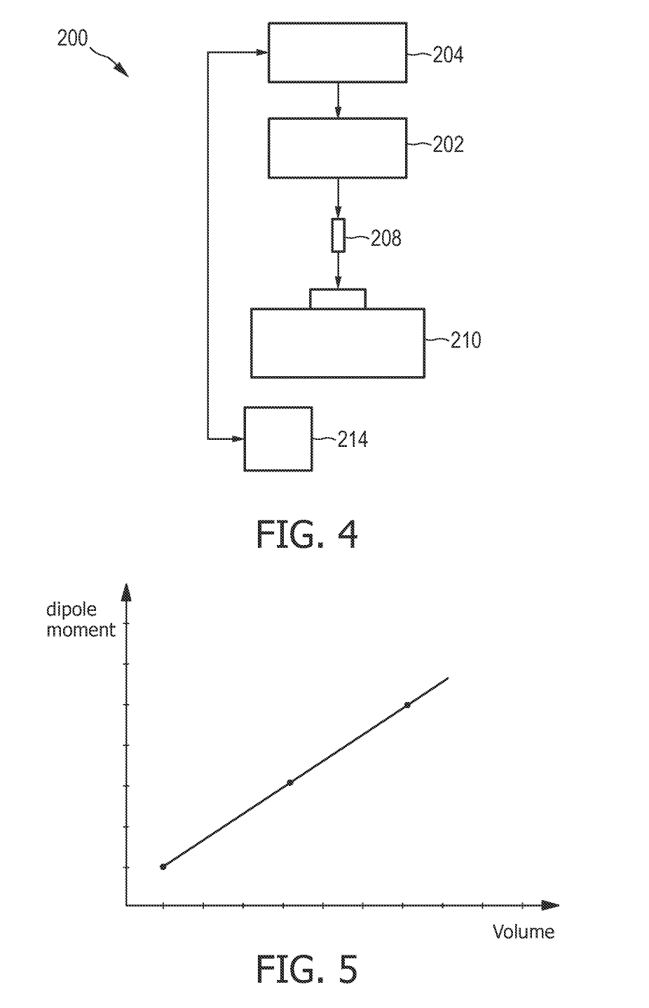

FIG. 4 shows a schematic drawing illustrating the method of the present invention which is generally denoted as 200. A first medium 202 to be characterized is provided. A second medium 204 is provided and added to the first medium 202. The second medium 204 comprises a magnetic tracer material or contains the magnetic particles 100 and is mixed with the first medium 200. The first medium 202 comprises a well-defined concentration C_{d} of active (drug) compound. The second medium 204 comprises a well-defined concentration Cₘ of particles 100 or magnetic tracer material. The first medium 202 has a volume V₁ and the second medium 204 has a volume V₂. The mixture of the first medium 202 and the second medium 204 results in a third medium 206 having the volume V₃=V₁+V₂.

From the third medium a small volume is extracted as a sample aliquot 208 to be measured by a magnetic spectrometer 210. The second medium 204 contains a concentration Cₘ of magnetic particles 100. A third medium 206 contains a concentration C_{m′} of magnetic particles 100. The concentration of magnetic material C_{m′} and the concentration of the active compound C_{d′} in the third medium 206 from which the sample aliquot 208 is extracted is

C_{m′}=Cₘ·(V₂/V₃) and C_{d′}=C_{d}·(V₁/V₃).

For evaluating of the measurement the magnetic spectrometer 210, a calibration factor C_{f} is derived from at least one calibration sample measurement having a known calibration volume CAL V₂ of the second medium 204. The calibration factor C_{f} is calculated from the measured magnetization UC₂ and the calibration volume, wherein C_{f}=UC₂/CAL V₂. Further, another calibration factor C_{f′} can be defined by using a known calibration volume CAL V₃ of the third medium 206. This calibration factor C_{f′} is C_{f′}=UC₃/CAL V₃. The two calibration factors C_{f}, C_{f′} scale with the effective concentration Cₘ, C_{m′} of magnetic particles 100. Therefore, the ratio of the calibration factor C_{f}, C_{f′} is given by C_{f}/C_{f′}=Cₘ/C_{m′}. The sample aliquot 208 is, as mentioned, above a small sample of the third medium 206. The volume of the sample aliquot 208 is given by V_{3′}=k·V₃, with k<<1, wherein the volume V_{3′} of a third medium 206 is known.

The magnetic spectrometer 210 measures the magnetization M of the sample aliquot 208 and provides the output U. Consequently U/V_{3′}=C_{f′}=C_{f}·Cₘ/C_{m′}. Therefore, the volume V_{3′} is V_{3′}=(U/C_{f}) (C_{m′}/Cₘ). The volume V_{1′} of the first medium 202 in the sample aliquot 208 can be calculated by the equation

V_{1′}=F₁·V_{3′}=F₁·(U/C_{f})(C_{m′}/Cₘ), (6)

wherein F₁ is the fraction of the first medium 202 in the third medium 206 and given by F₁=V₁/(V₁+V₂). Consequently the volume of the first medium 202 in the sample aliquot 208 can be derived from the measurement of the magnetization M of the sample aliquot 208 and the calibration factor C_{f}, C_{f′} derived from at least one calibration sample. This calculation is performed by an evaluation means 214, e.g. computer shown in FIGS. 1 and 4.

The amount of drug substance A_{d} in the sample aliquot 208 of the third medium 206 is given by A_{d}=C_{d}·V_{1′} or A_{d}=C_{d′}·V_{3′}.

In FIG. 5 a diagram of the magnetic dipole moment versus the volume of the measured calibration sample is shown. From the diagram shown in FIG. 5 a calibration curve can be derived by linear regression, which is more accurate than a single calibration measurement. The dipole moment can be derived from different calibration samples having a different volume or could be derived from one calibration sample, wherein sequentially after each measurement of the dipole moment at least one additional volume of magnetic material, e.g. the second medium 204 is injected into the calibration sample. From the calibration curve shown in FIG. 5, a calibration constant can be calculated as the average magnetic moment over the average volume.

In a preferred embodiment different volumes of the calibration sample are provided by injecting a defined volume of the second medium 204 into a biological tissue or e.g. transdermal into a patient's body.

By the present invention accurate measurements of small amounts and concentrations in fluids or solid materials can be obtained, which can be used in medical, biological assay and drug delivery devices including transdermal drug delivery. The invention relies on the use of an assay of magnetic particles that can be used as a tracer material for magnetic particle imaging and magnetic particle spectroscopy and that is uniformly dispersed, preferably colloidally, into a first medium of which small volumes or small changes in volume have to be detected. The method relies on the reliable quantification of tracer concentration, that is stretching over several decades. The method is intrinsically radiation free and can be translated into clinical application due to the non-toxicity of contrast agents, e.g. low-dose Fe oxide contrast agents. The system can be seen as essentially equivalent to a scintillation counter and can be translated into a clinical validation for transdermal drug delivery by use of a single-sided MPI scanner.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measured cannot be used to advantage.

Any reference signs in the claims should not be construed as limiting the scope.

1. An arrangement (10) for measuring small amounts of a first medium (202) in a third medium (206) and/or of a substance in the first medium (202), said third medium (206) comprising said first medium (202) and a second medium (204), said second medium (204) comprising a known concentration of a magnetic material, wherein said arrangement comprises:
magnetization means (12) for providing a variable magnetic field (20) in a region of action (22), in which a probe (18; 208) of said third medium (206) is placed for measurement,
receiving means (14) for acquiring a detection signal of the magnetization of said probe (12) in said region of action (22) after application of said variable magnetic field (20), and
evaluation means (214) for evaluating said detection signal and comparing it to calibration measurements of the magnetization of at least one calibration sample to derive an information about the amount of said first medium (202) in said third medium (206) and/or of said substance in said first medium (202).

2. An arrangement according to claim 1, characterized in that the magnetization means (12) are adapted for generating a magnetic selection field having a pattern in space of its magnetic field strength such that a first sub-zone having a low magnetic field strength and a second sub-zone having a higher magnetic field strength are formed in the region of action (22), wherein drive means are adapted for changing the position in space of the two sub-zones in the region of action (22) by means of a magnetic drive field so that the magnetization of the magnetic material changes locally.

3. An arrangement according to claim 1, characterized in that said calibration sample comprises a known volume of said second medium (204).

4. Arrangement according to claim 1, characterized in that said at least one calibration sample comprises a plurality of calibration samples having different concentrations of the magnetic material.

5. Arrangement according to claim 1, characterized in that said at least one calibration sample comprises a plurality of calibration samples having different volumes of said second medium (204).

6. Arrangement according to claim 1, characterized in that the magnetic field (20) is a homogeneous alternating magnetic field.

7. Arrangement according to claim 1, characterized in that said receiving means (14) are adapted for deriving said detection signal from the amplitude of one harmonic of the magnetic dipole moment.

8. Arrangement according to claim 1, characterized in that the magnetic field comprises one magnetic field strength.

9. Arrangement according to claim 1, characterized in that the magnetic field comprises different magnetic field strengths.

10. Arrangement according to claim 1, characterized in that the magnetic material comprises magnetic nanoparticles, in particular colloidally stabilised monodomain magnetic nanoparticles.

11. Arrangement according to claim 1, characterized in that the first medium is a medical or biological assay and the substance in the first medium is an active drug substance.

12. A method for measuring small amounts of a first medium (202) in a third medium (206) and/or of a substance in the first medium (202), said third medium (206) comprising said first medium (202) and a second medium (204), said second medium (204) comprising a known concentration of a magnetic material, which method comprises the steps of:
generating a variable magnetic field (20) in the region of action (22), in which a probe (18; 208) of said third medium (206) is placed for measurement,
acquiring a detection signal of the magnetization of said probe (18; 208) in said region of action (22) after application of said magnetic field (20), and
comparing said detection signal to calibration measurements of the magnetization of at least one calibration sample to derive an information about the amount of said first medium (202) in said third medium (206) and/or of said substance in said first medium (202).

13. Method according to claim 12, wherein said calibration measurements are derived from a plurality of calibration samples having different concentrations of the magnetic material.

14. Method according to claim 12, wherein said at least one calibration sample comprises a plurality of calibration samples having different volumes.

15. Method according to claim 12, wherein said at least one calibration sample is provided by injection of said second medium (204) into the third medium (206).
